(19) United States
(12) Patent Application Publication
(10) Pub. No.: US 2023/0223066 A1
(43) Pub. Date: Jul. 13, 2023

(54) MEMORY CELL AND METHODS THEREOF

(71) Applicant: Ferroelectric Memory GmbH, Dresden (DE)

(72) Inventor: Stefan Ferdinand Müller, Radebeul (DE)

(21) Appl. No.: 17/571,074

(22) Filed: Jan. 7, 2022

(51) Int. Cl. G11C 11/22; H01L 27/11507; H01L 27/11585; H01L 29/78; H01L 29/66

(52) U.S. Cl. CPC G11C 11/2275; G11C 11/223; G11C 11/2273; H01L 27/11507; H01L 27/11585; H01L 29/66795; H01L 29/78391

(57) ABSTRACT

Various aspects relate to a memory cell including a field-effect transistor structure and a capacitive memory structure, wherein the capacitive memory structure includes at least one spontaneously polarizable memory element, and wherein the field-effect transistor structure includes a source region, a drain region, a channel region extending between the source region and the drain region, and a gate structure disposed at the channel region, wherein the gate structure of the field-effect transistor structure substantially overlaps the source region of the field-effect transistor structure and/or the drain region of the field-effect transistor structure.

### TECHNICAL FIELD

Various aspects relate to an electronic device or at least a part of an electronic device, e.g., to a memory cell and methods thereof, e.g., a method for operating a memory cell.

### BACKGROUND

In general, various computer memory technologies have been developed in semiconductor industry. A fundamental building block of a computer memory may be referred to as memory cell. The memory cell may be an electronic circuit that is configured to store at least one information (e.g., bitwise). As an example, the memory cell may be selectively in one of at least two memory states representing, for example, a logic “1” and a logic “0”. In general, the information may be maintained (stored) in a memory cell until the memory state of the memory cell is modified, e.g., in a controlled manner. The information stored in the memory cell may be obtained (read out) by determining in which of the memory states the memory cell is residing in. At present, various types of memory cells may be used to store data. By way of example, a type of memory cell may include a thin film of a spontaneously polarizable material, e.g., a ferroelectric material or a configuration of an anti-ferroelectric material, whose polarization state may be changed in a controlled fashion to store data in the memory cell, e.g., in a volatile or non-volatile manner.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A and FIG. 1B show various aspects of a memory cell, e.g., of a field-effect transistor based capacitive memory cell, in a schematic view;

FIG. 2A and FIG. 2B show various aspects of electronic properties of a memory cell, e.g., an influence of a side capacitance on an operation of a field-effect transistor based capacitive memory cell;

FIGS. 3A to 3Fshow various aspects of a memory cell, e.g., of a field-effect transistor based capacitive memory cell, in a schematic view;

FIGS. 4A to 4D show various aspects of a memory cell, e.g., of a field-effect transistor based capacitive memory cell, in a schematic view; and

FIG. 5A and FIG. 5B show each a schematic flow diagram of a method of operating a memory cell, according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a memory cell, or a memory capacitor). However, it may be understood that aspects described in connection with methods may similarly apply to the devices, and vice versa.

Various aspects may be related to a read operation to read a field-effect transistor based capacitive memory cell more efficiently, e.g., to allow for a read out of the field-effect transistor based capacitive memory cell in the case that a floating node of the field-effect transistor based capacitive memory cell is charged during the data retention time, as explained in more detail below.

According to various aspects, a memory cell as described herein may include a field-effect transistor structure and a capacitive memory structure. The capacitive memory structure may be coupled to the field-effect transistor structure, e.g., to a floating gate of the field-effect transistor structure, and/or integrated in the field-effect transistor structure, e.g., integrated in a gate (e.g., in a gate stack) of the field-effect transistor structure. A memory cell that includes a field-effect transistor structure and a capacitive memory structure coupled to one another may be referred to as field-effect transistor based capacitive memory cell. In some aspects, the field-effect transistor based capacitive memory cell may include three terminals (also referred to as nodes), e.g., a gate terminal (also referred to as gate node), a first source/drain terminal (e.g., a source terminal, also referred to as source node), and second source/drain terminal (e.g., a drain terminal, also referred to as drain node). The field-effect transistor based capacitive memory cell may include a floating gate between the gate isolation of the field-effect transistor structure and a memory element of the capacitive memory structure. Since the floating gate is electrically isolated it may be possible that a charge can be transferred to the floating gate, e.g., due to one or more leakage currents assisted by an electrical field caused by the capacitive memory structure, such that the additional charge transferred to the floating gate may screen an actual memory state of the memory element and such that the field-effect transistor structure of the field-effect transistor based capacitive memory cell is not sensitive anymore for the actual memory state of the memory element.

According to various aspects, a capacitive memory structure may include a functional layer (e.g., a capacitive memory element) in a capacitive environment, e.g., disposed between two electrode layers or disposed between a channel of a field-effect transistor and an electrode layer (e.g., a gate electrode of the field-effect transistor). According to various aspects, a functional layer of a memory structure, e.g., of a capacitive memory structure such as a field-effect transistor based capacitive memory structure, may be spontaneously polarizable. According to various aspects, a capacitive memory element of a memory structure, e.g., of a capacitive memory structure such as a field-effect transistor based capacitive memory structure, may be spontaneously polarizable. A spontaneously polarizable layer may show a hysteresis in the (voltage dependent) polarization. The spontaneously polarizable layer may show anti-ferroelectric properties, e.g., the spontaneously polarizable layer may have no or no substantial remanent polarization remaining in the case that no voltage drops over the spontaneously polarizable layer. In other aspects, the spontaneously polarizable layer may show ferroelectric properties, e.g., the spontaneously polarizable layer may have a remanent polarization or a substantial remanent polarization remaining in the case that no voltage drops over the spontaneously polarizable layer.

According to various aspects, a functional layer (e.g., a spontaneously polarizable layer) of a memory structure, e.g., of a capacitive memory structure, may include or may be made of a spontaneously polarizable (e.g., an anti-ferroelectric and/or ferroelectric) material. According to various aspects, a capacitive memory element of a memory structure, e.g., of a capacitive memory structure, may include or may be made of a spontaneously polarizable (e.g., an anti-ferroelectric and/or ferroelectric) material. An anti-ferroelectric material may show a hysteresis in the (voltage dependent) polarization, however, with no or no substantial remanent polarization remaining in the case that no voltage drops over the anti-ferroelectric material. A ferroelectric material may show a hysteresis in the (voltage dependent) polarization, however, with a (e.g., substantial) remanent polarization remaining in the case that no voltage drops over the ferroelectric material.

According to various aspects, in various types of applications, e.g., in memory technology, a remanent polarization as low as 0 µC/cm² to 3 µC/cm² may be regarded as no substantial remanent polarization. Such low values of a remanent polarization may be present in a layer or material due to undesired effects, e.g., due to a not ideal layer formation. According to various aspects, in various types of applications, e.g., in memory technology, a remanent polarization greater than 3 µC/cm² may be regarded as substantial remanent polarization. Such a substantial remanent polarization may allow for storing information as a function of a polarization state of a spontaneously polarizable layer or a spontaneously polarizable material.

A polarization capability of a material (dielectric, spontaneous, and remanent polarization) may be analyzed using capacitance measurements (e.g., a spectroscopy), e.g., via a static (C-V) and/or time-resolved measurement or by polarization-voltage (P-V) or positive-up-negative-down (PUND) measurements. Another method for determining a polarization capability of a material may include transmission electron microscopy, e.g., an electric-field dependent transmission electron microscopy.

According to various aspects, a memory device may include a memory cell and a memory controller to operate (e.g., read and write) the memory cell. According to various aspects, a memory cell arrangement may include a memory cell and a memory controller to operate (e.g., read and write) the memory cell. It is noted that some aspects are described herein with reference to a memory cell of a memory device and/or with reference to a memory cell of memory cell arrangement; it is understood that a memory device and/or a memory cell arrangement may include a plurality of such described memory cells according to various aspects that can be operated in the same way by the memory controller, e.g., at the same time or in a time sequence. The memory cell arrangement may further include respective sets of control lines and voltage supply levels configured to operate the one or more memory cells of the memory device and/or the memory cell arrangement.

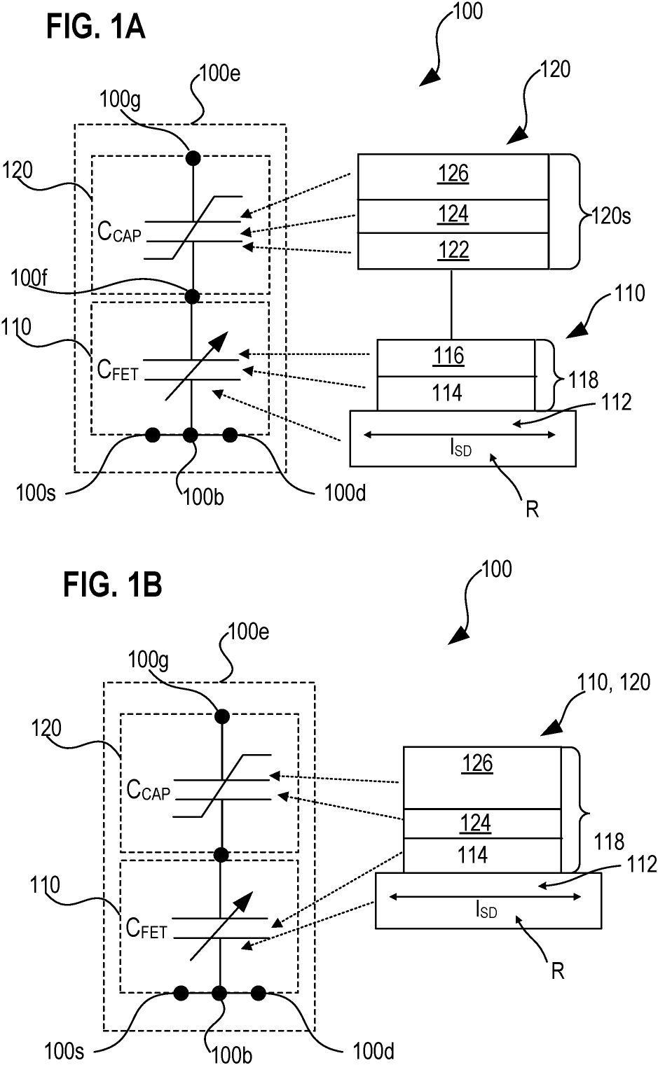

FIG. 1A and FIG. 1B show various aspects of a memory cell 100. The memory cell 100 may be a field-effect transistor based capacitive memory cell, according to various aspects. The memory cell 100 may include a field-effect transistor structure 110 and a capacitive memory structure 120. In some aspects, the capacitive memory structure 120 may be coupled to the field-effect transistor structure 110, see FIG. 1A, or the capacitive memory structure 120 may be, in other aspects, integrated into the field-effect transistor structure 110, see FIG. 1B. Basically, the memory cell 100 may include a field-effect transistor structure and a memory element (e.g., a spontaneously polarizable layer).

As illustrated in FIG. 1A, the capacitive memory structure 120 may include at least two electrodes 122, 126 (e.g., two electrode layers) and a memory element 124 coupled to the at least two electrodes 122, 126. The memory element 124 may include or may be a functional layer disposed between two electrodes 122, 126. The memory element 124 may include or may consist of any type of suitable memory material, as for example, a spontaneously polarizable material (e.g., a remanent polarizable material, e.g., a ferroelectric or anti-ferroelectric material). According to various aspects, the memory element 124 may be a capacitive memory element including, for example, an electrically non-conductive material such as a spontaneously polarizable material (e.g., a ferroelectric or anti-ferroelectric material) disposed between two electrodes. The capacitive memory structure 120 in a capacitive configuration may have a capacitance, C_{CAP}, associated therewith (see equivalent circuit 100e with respect to the capacitive properties). The two electrodes 122, 126 and the memory element 124 may form a memory layer stack 120s. In some aspects, the memory layer stack 120s may be a planar layer stack; however, other shapes may be suitable as well, e.g., curved shapes, angled shapes, coaxially aligned shapes, as examples. The capacitive memory structure 120 may be electrically connected to the field-effect transistor structure 110 (see FIG. 1A), e.g., to a gate structure 118 of the field-effect transistor structure 110, or integrated in a gate structure 118 of the field-effect transistor structure 110 (see FIG. 1B).

In more detail, the field-effect transistor structure 110 may include a gate structure 118, wherein the gate structure 118 may include a gate isolation 114 (also referred to as gate dielectric) and a gate electrode 116. It is noted that the gate electrode 116 of the field-effect transistor structure 110, that is, for example, in contact with the gate isolation 114, forms a floating gate node 100f of the memory cell 100 due to the capacitive memory structure 120 that is connected to or integrated in the gate structure 118 of the field-effect transistor structure 110. The gate structure 118 is illustrated exemplarily as a planar gate stack; however, it may be understood that the planar configuration shown in FIG. 1A is an example, and other field-effect transistor designs may include a gate structure 118 with a non-planar shape, for example a trench gate transistor design, a vertical field-effect transistor design, or other designs, such as a fin-FET design. The gate structure 118 may define a channel region 112, e.g., provided in a semiconductor portion (e.g., in a semiconductor layer, in a semiconductor die, etc.). The gate structure 118 may allow for a control of an electrical behavior (e.g., a resistance R) of the channel region 112, e.g., a current flow in the channel region 112 may be controlled (e.g., allowed, increased, prevented, decreased, etc.). In some aspects, the gate structure 118 may, for example, allow to control (e.g., allow or prevent) a source/drain current, I_{SD}, from a first source/drain region of the field-effect transistor structure 110 to a second source/drain region of the field-effect transistor structure 110 (the source/drains are provided in or adjacent to the channel but are not shown in FIG. 1A). The channel region 112 and the source/drain regions may be formed, e.g., via doping one or more semiconductor materials or by the use of intrinsically doped semiconductor materials, within a layer and/or over a layer. With respect to the operation of the field-effect transistor structure 110, a voltage may be provided (e.g., transferred to the floating gate node 100f of the memory cell 100) at the gate electrode 116 to control the current flow, I_{SD}, in the channel region 112, the current flow, I_{SD}, in the channel region 112 being caused by voltages supplied via the source/drain regions. The voltage provided (e.g., transferred to the floating gate node 100f of the memory cell 100) at the gate electrode 116 of the field-effect transistor structure 110 may be influenced by a gate voltage supplied to an (e.g., upper) electrode 126 of the capacitive memory structure 120 (e.g., the gate voltage supplied to the gate node 100g of the memory cell 100). The gate electrode 116 may include an electrically conductive material. According to various aspects, the gate isolation 114 may be configured to provide an electrical separation of the gate electrode 116 from the channel region 112 and further to influence the channel region 112 via an electric field generated by the gate electrode 116. The gate isolation 114 may include one or more electrically insulating layers, as an example.

In some aspects, the gate electrode 116 of the field-effect transistor structure 110 and the electrode 122 of the capacitive memory structure 120 that is connected to the field-effect transistor structure 110 may be spatially separated from one another and electrically connected via a conductive connection, e.g., one or more metal lines (see FIG. 1A). In other aspects, the gate electrode 116 of the field-effect transistor structure 110 and an (e.g., lower) electrode 126 of the capacitive memory structure 120 may be in direct physical contact with one another or implemented as a single (shared) electrode.

The field-effect transistor structure 110 may have a capacitance, C_{FET}, associated therewith (see equivalent circuit 100e with respect to the capacitive properties). According to various aspects, the field-effect transistor structure 110 and the capacitive memory structure 120 form together a field-effect transistor based capacitive memory structure, e.g., in a capacitive voltage divider configuration, as exemplarily shown in FIGS. 1A and 1B. According to various aspects, a gate node 100g of the memory cell 100 may be provided by the upper electrode 126 of the capacitive memory structure 120. The memory cell 100 may include a floating node 100f provided by the lower electrode 122 of the capacitive memory structure 120 and/or the gate electrode 116 of the field-effect transistor structure 110. One or more source/drain/bulk nodes 100s, 100d, 100 of the memory cell 100 may be provided by the source/drain/bulk regions of the field-effect transistor structure 110.

As illustrated in FIG. 1B, similar electric properties of the memory cell 100 may be obtained in the case that the memory element 124 of the memory cell 100 is integrated in the gate stack 118 of the field-effect transistor structure 110, compare equivalent circuit 100e in FIG. 1B with equivalent circuit 100e in FIG. 1A. However, the memory cell 100 shown in FIG. 1B may not have a dedicated floating node 100f since no additional conductive layer is disposed between the channel region 112 of the field-effect transistor structure 110 and the upper electrode 126 (e.g., the gate electrode of the memory cell 100) of the capacitive memory structure 120.

In the following, various aspects of a memory cell 100 with respect to their electrical characteristics are described in more detail. The memory cell 100 described herein may be used in connection with any type of suitable memory controller, e.g., a memory controller that may generate different voltage levels for writing the memory cell (e.g., for writing one or more memory cells of a memory cell arrangement) and/or reading the memory cell (e.g., for reading one or more memory cells of a memory cell arrangement).

According to various aspects, the memory cell and the memory cell arrangement described herein may be configured complementary metal oxide semiconductor (CMOS) compatible, e.g., including standard CMOS-materials only and may require no special integration considerations (e.g., no special thermal budget which may avoid diffusion and/or contamination during manufacturing). CMOS compatible spontaneously polarizable materials may be used to implement the one or more memory cell based on, for example, HfO₂ and/or ZrO₂. Doped HfO₂ (e.g., Si:HfO₂ or Al:HfO₂) or other suitable spontaneously polarizable materials may allow for an integration of the spontaneously polarizable layer via known integration schemes.

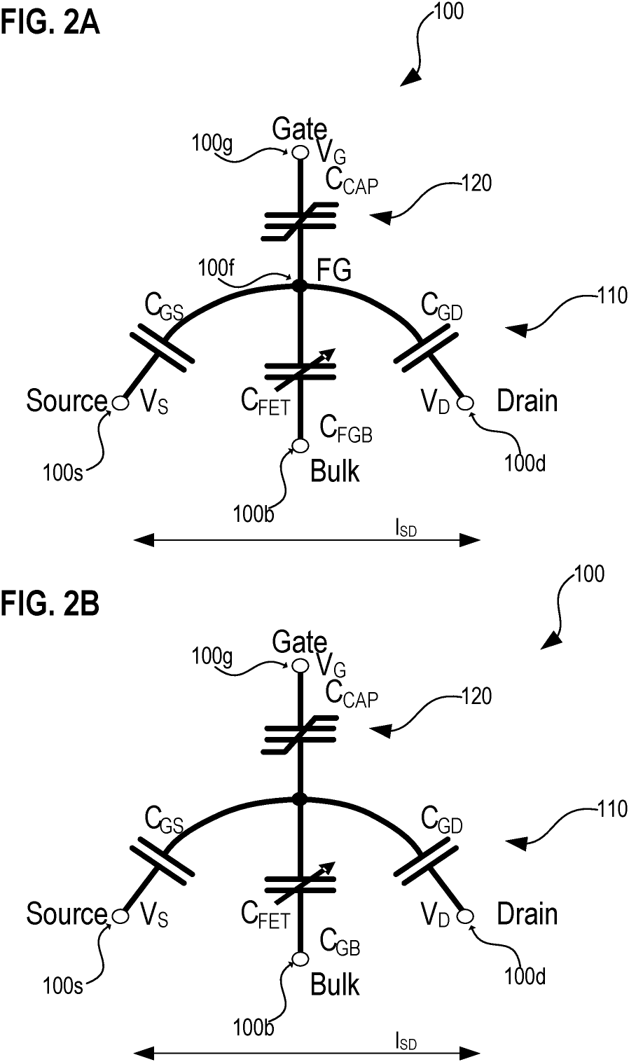

FIG. 2A and FIG. 2B illustrate electrical characteristics of a memory cell, e.g., of a memory cell 100 including a capacitive memory structure 120 and a field-effect transistor structure 110 as illustrated in FIGS. 1A and 1B. A current flow between a drain node 100d and a source node 100s of the memory cell 100 may be referred to as source/drain current, I_{SD}, or simply as drain current, I_{D}. The gate-source voltage drop associated with a gate structure (e.g., of a memory cell 100) may be defined by the respective voltages/potentials applied at the corresponding gate node (e.g., gate node 100g of the memory cell 100) and source node (e.g., source node 100s of the memory cell 100). The gate-source voltage drop may also be referred to as gate-source voltage, V_{GS}. In the case that the source voltage is zero, as used for example in conventional driving schemes for writing and/or reading of a field-effect transistor based memory cell, the gate-source voltage drop and the gate-source voltage, V_{GS}, may be referred to as gate voltage, V_{G} (e.g., applied at the gate node 100g of the memory cell 100). It is noted that a gate-drain voltage drop or a gate-bulk voltage drop may show the same or similar behavior as described herein with reference to the gate-source voltage drop. However, a reading of a memory cell 100 may include usually applying a gate-source voltage drop, V_{GS}, and determining a property of a resulting drain current, I_{D}.

FIG. 2A and FIG. 2B refer, for example, to various aspects of side capacitances and their influence on the operation of a capacitive memory cell, e.g., memory cell 100 having a field-effect transistor structure 110 and a capacitive memory structure 120. As explained with reference to FIG. 1A and FIG. 1B, a capacitive memory cell (e.g., a memory cell 100 including a field-effect transistor structure 110 and a spontaneously polarizable capacitive memory structure 120) can be described as series connection of a capacitive memory structure and the underlying field-effect transistor structure. The capacitive memory structure may be, for example, a ferroelectric capacitor (FeCAP), which may be referred to as metal-ferroelectric-metal (MFM) structure or metal-ferroelectric (MF) structure. The underlying field-effect transistor structure may be a MOSFET which may have a metal-insulator-semiconductor (MIS) structure or an insulator-semiconductor (IS) structure. The MIS structure or IS structure itself can be described as parallel connection of a gate/source (GS) capacitance C_{GS}, a gate-drain (GD) capacitance C_{GD}, and a floating-gate-bulk (FGB) capacitance C_{FGB} having respective capacitance values associated therewith. Commonly known devices may be configured to have lowest possible side capacitances (e.g., a low gate-source capacitance C_{GS} and a low gate-drain capacitance C_{GD}) to have an optimal control over the field-effect transistor structure. In this case, the capacitance C_{FET} associated with the field-effect transistor structure may be substantially defined by the floating-gate-bulk capacitance C_{FGB}. The floating-gate-bulk capacitance C_{FGB} is variable and a function of the gate potential due to the variable capacitance of the semiconductor. The gate-source and gate-drain capacitances C_{GS}, C_{GD} may be referred to as overlap capacitances or side capacitances. It is noted that the floating-gate-bulk capacitance C_{FGB} as referred to, for example, in FIG. 2A may be referred to as gate-bulk capacitance C_{GB} or only as bulk capacitance in the case that the memory cell 100 has no dedicated floating gate, see, for example, FIG. 2B.

Various aspects described herein may include a field-effect transistor structure as a functional part of a capacitive memory cell, wherein the field-effect transistor structure has overlap capacitances (see C_{GS} and/or C_{GD} in FIGS. 2A and 2B) specifically configured to improve the properties of a capacitive memory cell and its operation.

Compared to commonly used memory cells that include a field-effect transistor structure and a capacitive memory structure in a series connection, a memory cell may be provided that may include a comparatively great gate/drain overlap and/or a comparatively great gate/source overlap. In other words, compared to commonly used memory cells that include a field-effect transistor structure and a capacitive memory structure in a series connection, a memory cell may be provided that has a comparatively great gate/drain capacitance C_{GD} and/or a comparatively great gate/source capacitance C_{GS}. Adapting the overlap of the source and/or drain regions with reference to the gate may be obtained by various measures, e.g., by ion implantation, e.g., by etching and selective epitaxial deposition (e.g., of SiGe or SiC), to form source and drain areas as described herein. The desired overlap may be, for example, achieved by using a suitable implantation angle and/or implantation profile (e.g., considering dose, concentration, diffusion) or, in case an etch and epitaxial deposition process is used, by using suitable etch and deposition parameters for the respective overlap areas.

Various aspects of the memory cell may be described herein with reference to a planar field-effect transistor structure. However, the aspects described herein may be applied to FinFET-type structures, or nanosheet structures, nanowire structures, and/or forksheet structures in a similar way, e.g., by adjusting the respective source/drain overlaps in those particular process nodes.

According to various aspects, an increase of a side capacitance (e.g., of a drain/gate capacitance C_{GD} and/or of a source/gate capacitance C_{GS}) may result in an increased voltage drop over the capacitive memory structure 120 of a memory cell 100 due to the nature of the series connection of the respective side capacitance and the capacitance C_{CAP} of the capacitive memory structure 120. Due to the parallel connection of the side capacitances C_{GS}, C_{GD} with the capacitance C_{FET} - that is usually defined by the bulk capacitance - the overall capacitance of the field-effect transistor structure 110 is increased and the voltage drop over the series connected field-effect transistor structure 110 is decreased which results in an increased voltage drop over the capacitive memory structure 120.

Usually, a memory cell of a FeFET-type (or in general a memory cell 100 including a field-effect transistor structure 110 and a capacitive memory structure 120) are usually operated (e.g., written and/or inhibited) with substantially similar source/drain voltages to cause a breakdown to the bulk region to effectively distribute the gate/bulk voltage in the capacitive series connection, e.g., to apply a sufficiently high voltage over the capacitive memory structure 120 which defines the memory state of the memory cell 100. An example may be the so-called “Positive-Source-Drain-Erase-Scheme” (PSDES) which includes utilization of both source and drain voltage to erase the memory cell. However, according to various aspects, a suitably high side capacitance, e.g., resulting from the increased gate/source and/or gate/drain overlap, may allow for operating schemes that utilized only the drain or only the source voltage. This may save energy while operating the memory cell. Illustratively, the memory cell 100 may be effectively written (e.g., programmed, e.g., erased) or prevented from being written (e.g., inhibited) by applying a gate voltage V_{G} at the gate 100g of the memory cell 100 and a source voltage V_{S} at the source 100s of the memory cell 100 and leaving the voltage at the drain 100d of the memory cell 100 floating, lower than the source voltage Vs, or zero; or the memory cell 100 may be effectively written (e.g., programmed, e.g., erased) or prevented from being written (e.g., inhibited) by applying a gate voltage V_{G} at the gate 100g of the memory cell 100 and a drain voltage V_{D} at the drain 100d of the memory cell 100 and leaving the voltage at the source 100s of the memory cell 100 floating, lower than drain voltage V_{D}, or zero.

In the following, various implementations are described in which a field-effect transistor structure 110 of a memory cell includes features to cause a suitably high side capacitance to efficiently operated (e.g., to program, to erase, to inhibit) the memory cell.

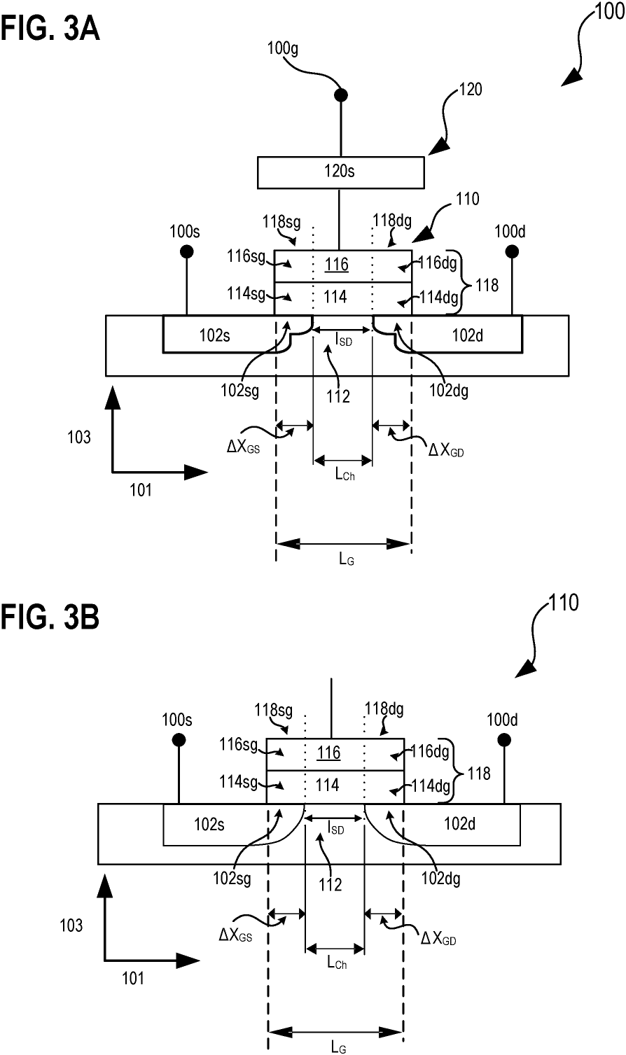

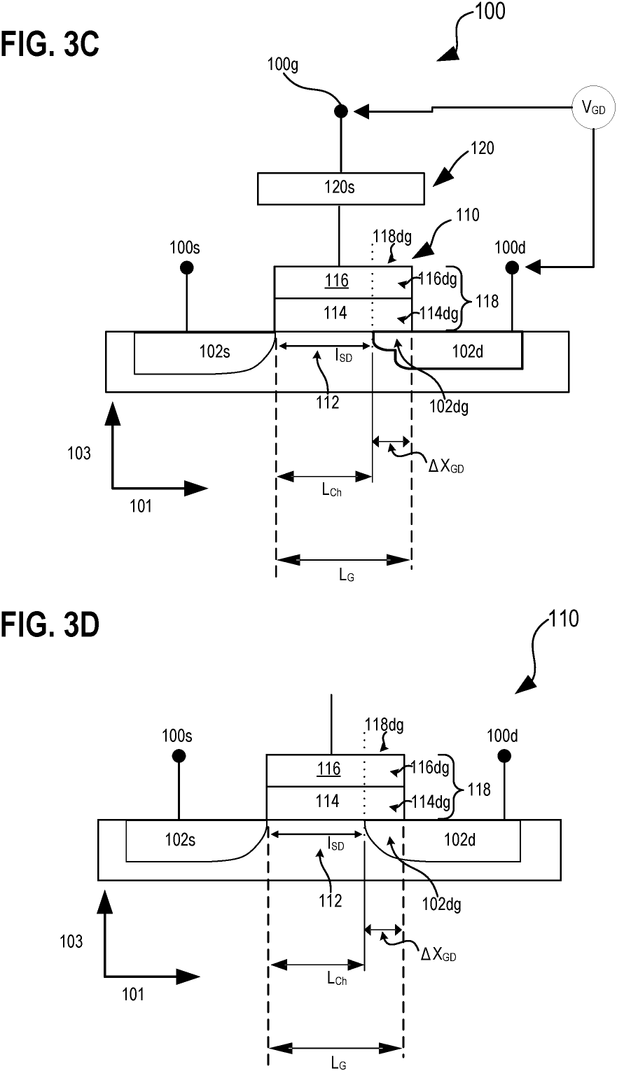

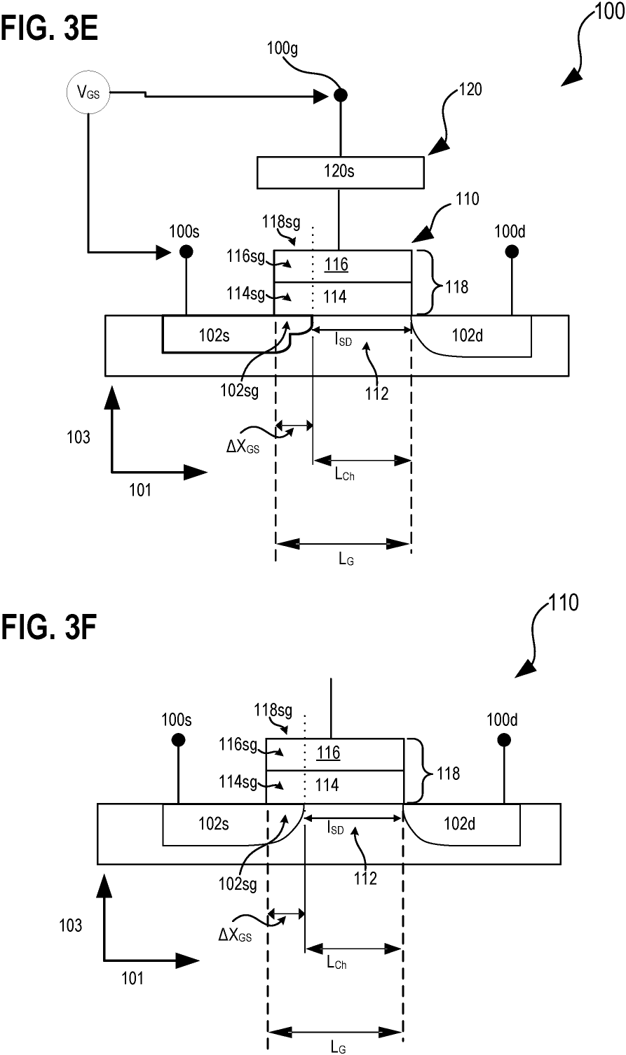

FIG. 3A and FIG. 3B show a field-effect transistor structure 110 of a memory cell 100 that includes both a gate/source overlap ΔX_{GS} and a gate/drain overlap ΔX_{GD}, according to various aspects. In other aspects, the field-effect transistor structure 110 of the memory cell 100 may have only a gate/drain overlap ΔX_{GD} as shown in FIG. 3C and FIG. 3D. In still other aspects, the field-effect transistor structure 110 of the memory cell 100 may have only a gate/source overlap ΔX_{GS} as shown in FIG. 3E and FIG. 3F. As illustrated in FIGS. 3A, 3C, and 3E, at least the source region 102s or at least the drain region 102d of the field-effect transistor structure 110 may have at least a two-implant doping profile to increase the extension of the source region 102s or the drain region 102b below the gate structure 118. However, other types of implementations may include a single implant doping profile the respective region as illustrated in FIGS. 3B, 3D, and 3F.

According to various aspects, the field-effect transistor structure 110 illustrated in FIGS. 3A to 3F may be a functional part of a field-effect transistor based capacitive memory cell 100. As described exemplarily above with references to FIGS. 1A to 2B, a field-effect transistor based capacitive memory cell (e.g., memory cell 100) may include a field-effect transistor structure 110 and a capacitive memory structure 120, wherein the capacitive memory structure 120 includes at least one spontaneously polarizable layer 124 (e.g., a ferroelectric layer). The field-effect transistor structure 110 may include, as usual for a structure with field-effect transistor properties, a source region 102s, a drain region 102d, a channel region 112 extending between the source region 102s and the drain region 102d, and a gate structure 118 disposed at the channel region 112.

According to various aspects, the gate structure 118 substantially overlaps the source region 102s and/or the drain region 102d. In various field-effect transistor technologies avoid a substantial gate/source overlap ΔX_{GS} and/or gate/drain overlap ΔX_{GD}, since the control over the transistor function may be reduced with an increased side capacities C_{GS}, C_{GD} of the field-effect transistor structure 110. However, in some applications, as described herein, it may be acceptable to trade of the controllability of the field-effect transistor structure 110 for a better control over the capacitive memory structure 120, since the field-effect transistor structure 110 may have, in the memory cell 100, a function related of controlling the capacitive memory structure 120 and the electronic properties (e.g., switching time, e.g., channel resistance, e.g., threshold voltage, e.g., breakdown voltage) of the field-effect transistor structure 110 itself may be of less importance compared to the proper control (e.g., switching, e.g., retention) of the capacitive memory structure 120.

The field-effect transistor structure 110 is illustrated in FIGS. 3A to 3F as a planar device. However, various other types of field-effect transistor structures may show the same beneficial properties in the case that they are designed with a substantial gate/source overlap ΔX_{GS} and/or gate/drain overlap ΔX_{GD} as described herein.

In some aspects, as illustrated in FIGS. 3A and 3B, the gate/source and the gate/drain overlap may be substantially equal, i.e., the field-effect transistor structure 110 may have a symmetric configuration with respect to the gate, the source, and the drain. However, according to other aspects, as illustrated in FIGS. 3C to 3F, an overlap of the gate structure 118 with the source region 102s (see, for example, ΔX_{GS}) may be different (e.g., greater or less) from an overlap of the gate structure 118 with the drain region 102d (see, for example, ΔX_{GD}). In other words, the field-effect transistor structure 110 may have an asymmetric configuration with respect to the gate, the source, and the drain.

According to various aspects, as illustrated in FIGS. 3C and 3D, the gate structure 118 may substantially overlap the drain region 102d and may not (or not substantially) overlap the source region 102s. This may lead to an asymmetric configuration such that a capacitance associated with the drain region and the gate structure (see, for example, ΔX_{GD}) is different from (e.g., greater than) a capacitance associated with the source region and the gate structure (see, for example, ΔX_{GS}). This may allow for an operation (e.g., an erase of the capacitive memory structure 120 coupled to the field-effect transistor structure 110) based on a gate/drain voltage (V_{GD}) without applying a substantial gate/source voltage (V_{GS}).

According to various aspects, as illustrated in FIGS. 3E and 3F, the gate structure 118 may substantially overlap the source region 102s and may not (or not substantially) overlap the drain region 102d. This may lead to an asymmetric configuration such that a capacitance associated with the source region and the gate structure (see, for example, ΔX_{GS}) is different from (e.g., greater than) a capacitance associated with the drain region and the gate structure (see, for example, ΔX_{GD}). This may allow for an operation (e.g., an erase of the capacitive memory structure 120 coupled to the field-effect transistor structure 110) based on a gate/source voltage (V_{GS}) without applying a substantial gate/drain voltage (V_{GD}).

According to various aspects, a length of an overlap of the gate structure 118 with the source region 102s (see, for example, ΔX_{GS}) may be greater than 5 nm. In some aspects, a substantial overlap of the gate structure 118 with the source region 102s may be desired and may not be a result of non-ideal process conditions or tolerances during manufacturing. A substantial overlap of the gate structure 118 with the source region 102s may be defined either in absolute values (e.g., greater than 2 nm, e.g., greater than 5 nm, e.g., greater than 10 nm) or in relative values. As an example for relative values, a substantial overlap of the gate structure 118 with the source region 102s may be defined relative to a length L_{G} of the gate structure 118, e.g., greater than 5% of the gate structure length L_{G}, e.g., greater than 10% of the gate structure length L_{G}, e.g., greater than 20% of the gate structure length L_{G}, or relative to a length L_{Ch} of the channel, 112 e.g., greater than 5% of the channel length L_{Ch}, e.g., greater than 10% of the channel length L_{Ch}, e.g., greater than 20% of the channel length L_{Ch}.

According to various aspects, a length of an overlap of the gate structure 118 with the drain region 102d (see, for example, ΔX_{GS}) may be greater than 5 nm. In some aspects, a substantial overlap of the gate structure with the drain region 102d may be desired and may not be a result of non-ideal process conditions or tolerances during manufacturing. A substantial overlap of the gate structure 118 with the drain region 102d may be defined either in absolute values (e.g., greater than 2 nm, e.g., greater than 5 nm, e.g., greater than 10 nm) or in relative values. As an example for relative values, a substantial overlap of the gate structure 118 with the drain region 102d may be defined relative to a length L_{G} of the gate structure 118, e.g., greater than 5% of the gate structure length L_{G}, e.g., greater than 10% of the gate structure length L_{G}, e.g., greater than 20% of the gate structure length L_{G}, or relative to a length L_{Ch} of the channel 112, e.g., greater than 5% of the channel length L_{Ch}, e.g., greater than 10% of the channel length L_{Ch}, e.g., greater than 20% of the channel length L_{Ch}.

According to various aspects, the length L_{G} of the gate structure 118 may be also referred to as gate length. The gate length may be defined by the extension of the gate structure 118 (e.g., the gate electrode 116) along the channel 112. In a planar configuration, as illustrated in FIGS. 3A to 3F, the length L_{G} of the gate structure 118 may be defined as the length of the gate electrode 116 along a lateral direction 101 (e.g., perpendicular to a height direction 103). In other configurations, e.g., in the case that the field-effect transistor structure has a trench configuration, the length of the gate electrode 116 may be defined (e.g., as a curved line) along a curved channel.

According to various aspects, as illustrated in FIGS. 3A to 3F, a drain overlap portion 118dg of the gate structure 118 may be in direct physical contact with a portion 102dg of the drain region 102d. The drain overlap portion 118dg of the gate structure 118 may include a drain overlap portion 116dg of the gate electrode 116 and a drain overlap portion 114dg of the gate isolation 114. The drain overlap portion 114dg of the gate isolation 114 may be in direct physical contact with the portion 102dg of the drain region 102d. Furthermore, a source overlap portion 118sg of the gate structure 118 may be in direct physical contact with a portion 102sg of the source region 102s. The source overlap portion 118sg of the gate structure 118 may include a source overlap portion 116sg of the gate electrode 116 and a source overlap portion 114sg of the gate isolation 114. The source overlap portion 114sg of the gate isolation 114 may be in direct physical contact with the portion 102sg of the source region 102s.

In some aspects, a length of the drain overlap portion 118dg of the gate structure 118 may be equal to a length of the source overlap portion 118sg of the gate structure 118, e.g., in the case that the field-effect transistor structure 110 has a symmetric configuration, see, for example, FIG. 3A and FIG. 3B. In other aspects, a length of the drain overlap portion 118dg of the gate structure 118 is different from (e.g., less than or greater than) a length of the source overlap portion 118sg of the gate structure 118. The length of the source overlap portion 118sg and/or the length of the drain source overlap portion 118dg may be defined by the extension of the respective portion 118sd, 118dg along the channel 112 of the field-effect transistor structure 110. In a planar configuration, as illustrated in FIGS. 3A to 3F, the length of the respective portion 118sd, 118dg may be defined as along the lateral direction 101 (e.g., perpendicular to a height direction 103). In other configurations, e.g., in the case that the field-effect transistor structure has a trench configuration, the length of the respective portion 118sd, 118dg may be defined (e.g., as a curved line) along a curved channel.

According to various aspects, the gate structure 118 may define the gate length L_{G}, wherein the channel length L_{Ch} of the field-effect transistor structure 110 may be substantially shorter than the gate length L_{G}, as illustrated, for example, in FIGS. 3A to 3F. As an example, the channel length may be in the range from about 20% to about 90% of the gate length L_{G}, e.g., in the range from about 20% to about 80% of the gate length L_{G}.

According to various aspects, the length direction may be understood as the lateral direction 101 shown in FIGS. 3A to 3F. The length direction may define the channel length L_{Ch}, the gate length L_{G}, and the length of an overlap (e.g., the gate/drain overlap ΔX_{GD} and/or the gate/source overlap ΔX_{GS}) may be defined, in some aspects, by a shortest distance along the channel region between the drain region 102d and the source region 102d. In other words, the channel length and other length directions and the overlap described herein may be defined along a spatial course of the channel 112.

According to various aspects, the channel region 112 of the field-effect transistor structure 110 may be provided by semiconductor material (e.g., having a predefined doping content). In some aspects, the source region 102s may have a doping content greater than the predefined doping content of the semiconductor material. In some aspects, the source region 102s may have a doping content greater than about 10¹⁸ /cm³. In some aspects, the drain region 102d may have a doping content greater than the predefined doping content of the semiconductor material. In some aspects, the drain region 102s may have a doping content greater than about 10¹⁸ /cm³. According to various aspects, the channel region 112 of the field-effect transistor structure 110 may have a doping content that is at least one order of magnitude lower than the doping content of the source region and/or of the drain region. The doping content may define the respective dimensions of the source region 102s, the drain region 102d, and therefore the channel length L_{Ch} and the length of the gate/source and gate/drain overlaps ΔX_{GS}, ΔX_{GD}.

In some aspects, a lateral doping profile of the source region 102s may be equal to a lateral doping profile of the drain region 102d, as illustrated, for example, in FIGS. 3A and 3B. In other aspects, a lateral doping profile of the source region 102s may be different from a lateral doping profile of the drain region 102d, as illustrated, for example, in FIGS. 3C to 3F.

Various aspects are directed to a memory device, wherein the memory device includes: a field-effect transistor based capacitive memory cell (e.g., memory cell 100 as described herein) including a field-effect transistor structure (e.g., field-effect transistor structure 110) and a capacitive memory structure (e.g., capacitive memory structure 120), wherein the capacitive memory structure includes at least one spontaneously polarizable layer (e.g., a layer of a ferroelectric material), and wherein the field-effect transistor structure includes a source region (e.g., source region 102s), a drain region (e.g., drain region 102d), a channel region (e.g., channel region 112) extending between the source region and the drain region, and a gate structure (e.g., gate structure 118) disposed at the channel region, wherein the gate structure substantially overlaps the source region and/or the drain region. It may be crucial to implement the field-effect transistor structure of a field-effect transistor based capacitive memory cell with a gate structure that substantially overlaps the source region and/or the drain region to provide a substantial side capacitance to control the memory operations (e.g., an erase operation, an inhibit operation) of the field-effect transistor based capacitive memory cell via either the source terminal or the drain terminal. It may be beneficial to charge and supply only one of the terminals of the memory cell (either the source terminal or the drain terminal and therefore either the source-line or the bit line) and still cause a proper memory operation.

Various aspects are directed to a memory device, wherein the memory device includes: a field-effect transistor based capacitive memory cell (e.g., memory cell 100 as described herein) including a field-effect transistor structure (e.g., field-effect transistor structure 110) and a capacitive memory structure (e.g., capacitive memory structure 120), wherein the capacitive memory structure includes at least one spontaneously polarizable layer (e.g., a layer of a ferroelectric material), and wherein the field-effect transistor structure includes a source region (e.g., source region 102s), a drain region (e.g., drain region 102d), a channel region (e.g., channel region 112) extending between the source region and the drain region, and a gate structure (e.g., gate structure 118) disposed at the channel region, wherein the gate structure includes a gate electrode (e.g., gate electrode 116) defining a gate length (e.g., gate length L_{G}), and wherein a channel length (e.g., channel length L_{Ch}) of the channel region is substantially shorter than the gate length. As examples, the channel length may be at least shorter than 90% of the gate length, preferably at least shorter than 80% of the gate length. It may be crucial to implement the field-effect transistor structure of a field-effect transistor based capacitive memory cell with a channel length that is substantially shorter than the gate length to provide a substantial side capacitance to control the memory cell operations (e.g., an erase operation, an inhibit operation) of the field-effect transistor based capacitive memory cell via either the source terminal or the drain terminal. It may be beneficial to charge and supply only one of the terminals of the memory cell (either the source terminal or the drain terminal and therefore either the source-line or the bit line) and still cause a proper memory cell operation.

Various aspects are directed to a memory device, wherein the memory device includes: a field-effect transistor based capacitive memory cell (e.g., memory cell 100 as described herein) including a field-effect transistor structure (e.g., field-effect transistor structure 110) and a capacitive memory structure (e.g., capacitive memory structure 120), wherein the capacitive memory structure includes at least one spontaneously polarizable layer (e.g., a layer of a ferroelectric material), and wherein the field-effect transistor structure includes a source region (e.g., source region 102s), a drain region (e.g., drain region 102d), a channel region (e.g., channel region 112) extending between the source region and the drain region, and a gate structure (e.g., gate structure 118) disposed at the channel region, wherein an overlap of the gate structure with the source region is different from an overlap of the gate structure with the drain region. Various aspects are directed to a memory device, wherein the memory device includes: a field-effect transistor based capacitive memory cell (e.g., memory cell 100 as described herein) including a field-effect transistor structure (e.g., field-effect transistor structure 110) and a capacitive memory structure (e.g., capacitive memory structure 120), wherein the capacitive memory structure includes at least one spontaneously polarizable layer (e.g., a layer of a ferroelectric material), and wherein the field-effect transistor structure includes a source region (e.g., source region 102s), a drain region (e.g., drain region 102d), a channel region (e.g., channel region 112) extending between the source region and the drain region, and a gate structure (e.g., gate structure 118) disposed at the channel region, wherein the gate structure overlaps the source region and the drain region in an asymmetric configuration such that a capacitance associated with the drain region and the gate structure is different from a capacitance associated with the source region and the gate structure. It may be sufficient and beneficial to charge and supply only one of the terminals of the memory cell (either the source terminal or the drain terminal and therefore either the source-line or the bit line) and still cause a proper memory dell operation. Therefore, an aspect may include to implement the overlap of the gate structure at the terminal that is indented to control the memory cell operation, e.g., either at the source terminal (i.e., at the source region) or at the drain terminal (i.e., at the drain region).

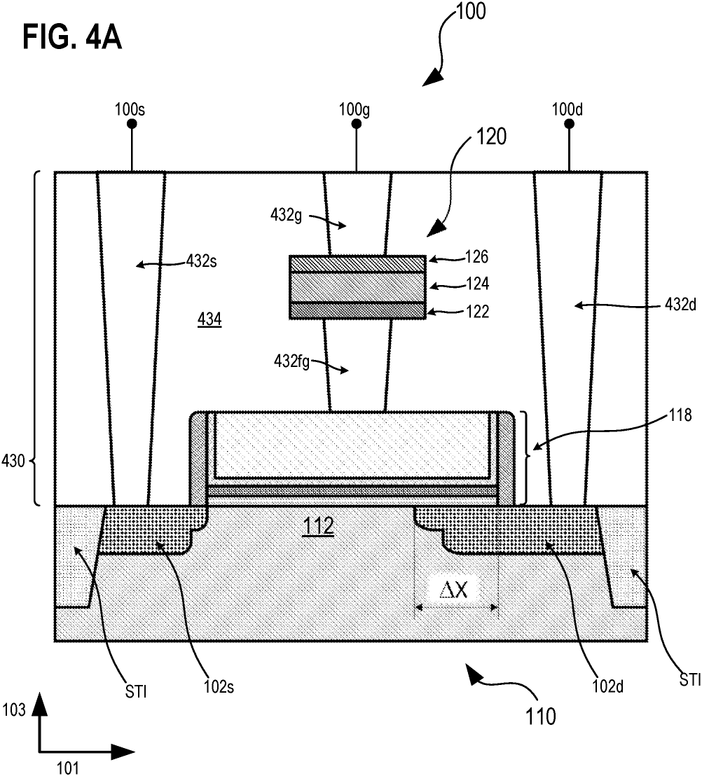

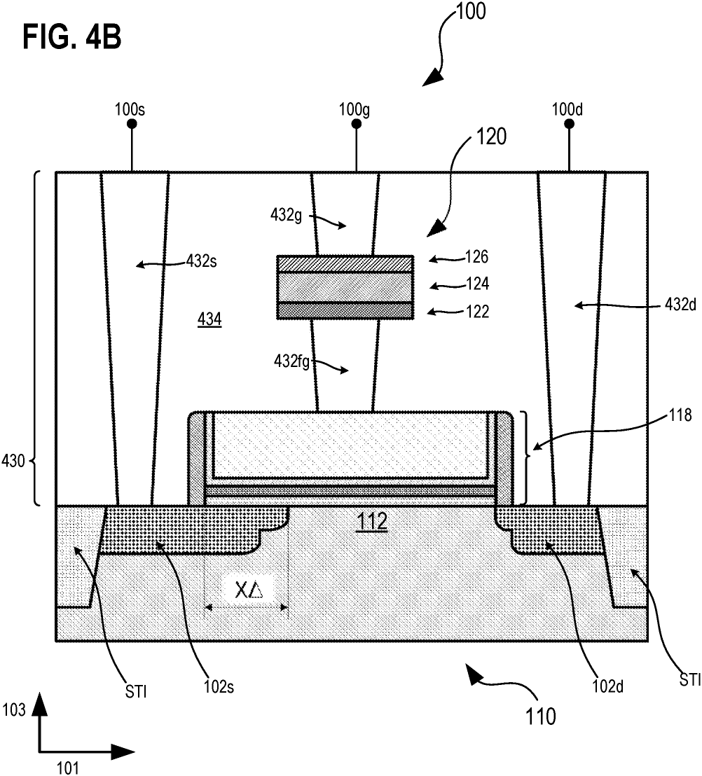

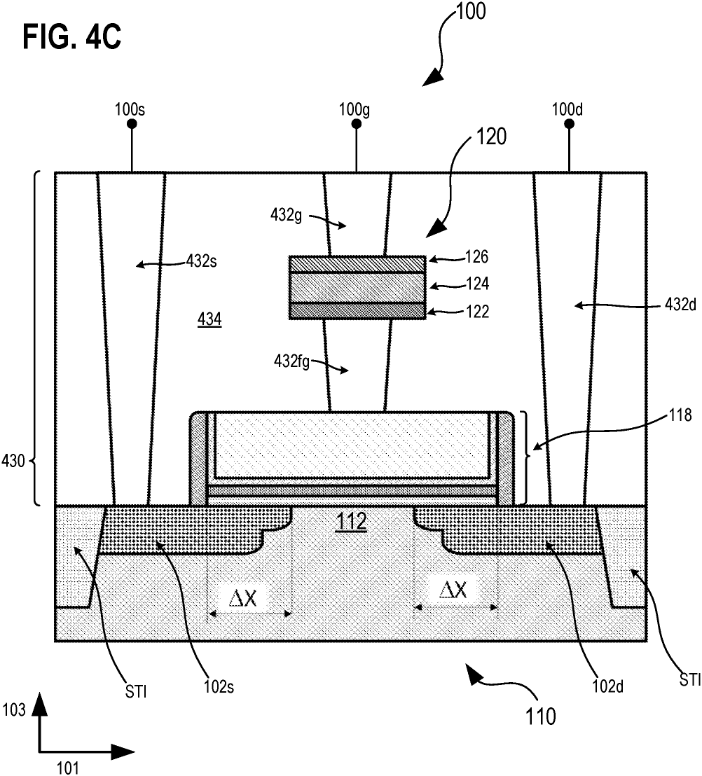

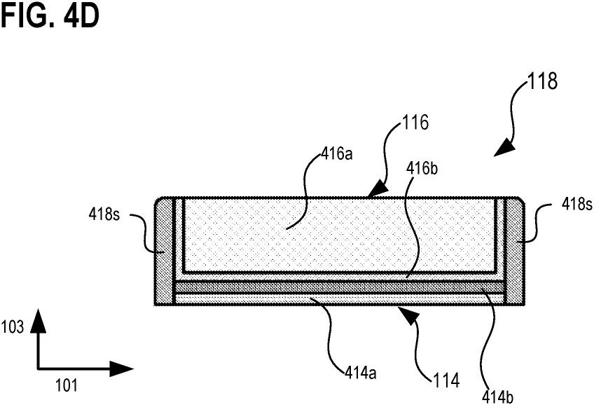

Various implementations of a memory device or a memory cell 100 (e.g., a field-effect transistor based capacitive memory cell) are illustrated in FIG. 4A, FIG. 4B, and FIG. 4C, wherein the gate structure 118 (in particular the gate electrode 116 of the gate structure 118) overlaps (see ΔX) at least one of the source region 102s and/or the drain region 102d.

According to various aspects, a transistor area may be defined by one or more shallow trench isolations STI. The one or more shallow trench isolations STI may include silicon oxide. A contact structure 430 (e.g., a contact metallization) may be configured to contact the source region 102s via a source contact 432s and the drain region 102d via a drain contact 432d. The capacitive memory structure 120 of the memory cell 100 may be contacted via a gate contact 432g and a connection of the capacitive memory structure 120 and the field-effect transistor structure 110 with one another may be provided by a floating gate contact 432fg. According to various aspects, the source contact 432s, the drain contact 432d, the gate contact 432g, and the floating gate contact 432fg may include tungsten or any other suitable contact metal. The source contact 432s, the drain contact 432d, the gate contact 432g, and the floating gate contact 432fg may be at least partially embedded in a dielectric material 434 (e.g., silicon oxide, silicon nitride, or any other suitable electrically non-conductive material).

According to various aspects, the source region 102s and the drain region 102d may be of a doping type (e.g., n++ or p++) opposite to the doping type of the channel region 112 (e.g., p+, n+)

According to some aspects, the gate structure 118 may include a gate electrode 116 that includes a metal gate layer 416b (e.g., a titanium nitride layer) and a gate portion 416a (e.g., a polysilicon gate), see, for example, FIG. 4D that is a more detail via of the gate structure 118 illustrated in FIGS. 4A to 4C. According to some aspects, the gate structure 118 may include a gate isolation 114 that includes a first gate isolation layer 414a (e.g., a low-k isolation layer, e.g., a silicon oxide layer, e.g., a silicon oxynitride layer) and a second gate isolation layer 414b (e.g., a high-k isolation layer, e.g., a dielectric hafnium oxide layer) see, for example, FIG. 4D. According to various aspects, the gate structure 118 may include a sidewall spacer 418s (e.g., a silicon nitride spacer) that partially surrounds the gate isolation 114 and the gate electrode 116, see, for example, FIG. 4D.

According to various aspects, the capacitive memory structure 120 of the memory cell 100 may include a bottom electrode 122 (e.g., a titanium nitride bottom electrode) and a top electrode 126 (e.g., a titanium nitride top electrode) and the memory element 124 may include ferroelectric HfO, ferroelectric ZrO, and/or ferroelectric HfₓZr_{y}O₂ (with x and/or y in the range from about ¼ to about ¾ and with x+y about 1).

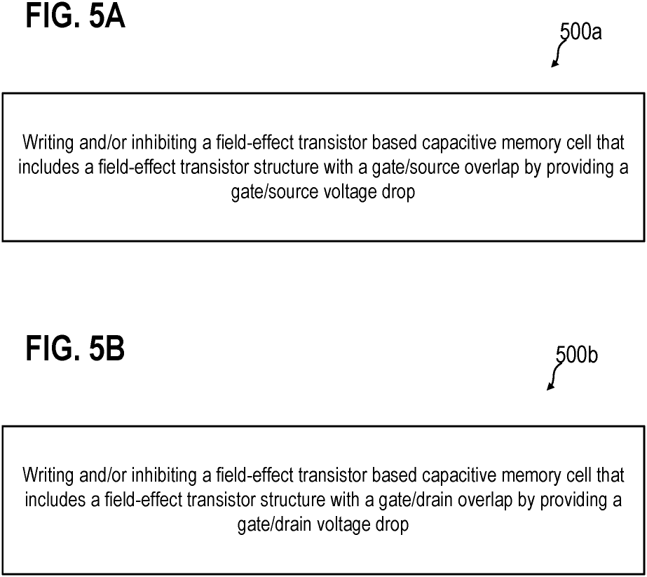

FIG. 5A and FIG. 5B show each a schematic flow diagram of a method for operating a field-effect transistor based capacitive memory cell. Operating the field-effect transistor based capacitive memory cell (e.g., memory cell 100 described herein) may include writing (e.g., programming, erasing, and/or inhibiting) the field-effect transistor based capacitive memory cell. In some aspects, a field-effect transistor based capacitive memory cell (e.g., memory cell 100 described herein) may be written (e.g., erased and/or programmed) and/or inhibited by providing a gate/source voltage drop (see, for example, V_{GS} in FIG. 3E) in the case that the field-effect transistor based capacitive memory cell has a field-effect transistor structure with a gate/source overlap (see, for example, FIG. 3E and FIG. 4B). In other aspects, a field-effect transistor based capacitive memory cell (e.g., memory cell 100 described herein) may be written (e.g., erased or programmed) and/or inhibited by providing a gate/drain voltage drop (see, for example, V_{GD} in FIG. 3C) in the case that the field-effect transistor based capacitive memory cell has a field-effect transistor structure with a gate/drain overlap (see, for example, FIG. 3C and FIG. 4A). The writing and/or inhibiting may be applied as well in the case that the field-effect transistor structure has a gate/drain overlap in addition to the gate/source overlap or a gate/source overlap in addition to the gate/drain overlap (see, for example, FIG. 3A and FIG. 4C).

Method 500a illustrated in FIG. 5A may include writing and/or inhibiting (e.g., prevent writing in the case that other memory cell of an array that share one or more control lines are written) a field-effect transistor based capacitive memory cell that includes a field-effect transistor structure with a gate/source overlap (e.g., memory cell 100 described herein with reference to FIGS. 3A, 3E, 4B, and 4C) by providing a gate/source voltage drop (see, for example, V_{GS} in FIG. 3E).

Method 500b illustrated in FIG. 5B may include writing and/or inhibiting (e.g., prevent writing in the case that other memory cell of an array that share one or more control lines are written) a field-effect transistor based capacitive memory cell that includes a field-effect transistor structure with a gate/drain overlap (e.g., memory cell 100 described herein with reference to FIGS. 3A, 3C, 4A, and 4C)) by providing a gate/drain voltage drop (see, for example, V_{GD} in FIG. 3C).

In the following, various examples are provided that refer to the memory cell 100, a memory controller, a memory device or the memory cell arrangement and an operation of the memory cell, the memory controller, and the memory device or the memory cell arrangement.

Example 1 is a memory device, including a field-effect transistor based capacitive memory cell, the field-effect transistor based capacitive memory cell including a field-effect transistor structure and a capacitive memory structure, the capacitive memory structure including at least one spontaneously polarizable layer and the field-effect transistor structure including a source region, a drain region, a channel region extending between the source region and the drain region, and a gate structure disposed at the channel region. Another Example 1 is a memory cell (e.g., a field-effect transistor based capacitive memory cell), the memory cell including a field-effect transistor structure and a capacitive memory structure, the capacitive memory structure including at least one spontaneously polarizable layer and the field-effect transistor structure including a source region, a drain region, a channel region extending between the source region and the drain region, and a gate structure disposed at the channel region.

In Example 2, the memory device or the memory cell of Example 1 may optionally include that the gate structure substantially overlaps the source region and/or the drain region.

In Example 3, the memory device or the memory cell of Example 1 or 2 may optionally include that an overlap of the gate structure with the source region is different from an overlap of the gate structure with the drain region.

In Example 4, the memory device or the memory cell of any one of Examples 1 to 3 may optionally include that the gate structure overlaps the source region and the drain region in an asymmetric configuration such that a capacitance associated with the drain region and the gate structure is different from a capacitance associated with the source region and the gate structure.

In Example 5, the memory device or the memory cell of any one of Examples 1 to 4 may optionally include that a length of an overlap of the gate structure with the source region is greater than 5 nm, e.g., in the range from about 5 nm to about 30 nm.

In Example 6, the memory device or the memory cell of any one of Examples 1 to 5 may optionally include that a length of an overlap of the gate structure with the drain region is greater than 5 nm, e.g., in the range from about 5 nm to about 30 nm.

In Example 7, the memory device or the memory cell of Example 5 may optionally include that a length of an overlap of the gate structure with the drain region is less than 2 nm.

In Example 8, the memory device or the memory cell of Example 6 may optionally include that a length of an overlap of the gate structure with the source region is less than 2 nm.

In Example 9, the memory device or the memory cell of any one of Examples 1 to 8 may optionally include that a drain overlap portion of the gate structure (e.g., a drain overlap portion of a gate isolation of the gate structure) is in direct physical contact with a portion of the drain region, and wherein a source overlap portion of the gate structure (e.g., a source overlap portion of the gate isolation of the gate structure) is in direct physical contact with a portion of the source region.

In Example 10, the memory device or the memory cell of Example 9 may optionally include that a length of the drain overlap portion of the gate structure is equal to a length of the source overlap portion of the gate structure.

In Example 11, the memory device or the memory cell of Example 9 may optionally include that a length of the drain overlap portion of the gate structure is different from (e.g., less than or greater than) a length of the source overlap portion of the gate structure.

In Example 12, the memory device or the memory cell of any one of Examples 1 to 11 may optionally include that the gate structure defines a gate length, and that a channel length of the field-effect transistor structure is substantially shorter than the gate length.

In Example 13, the memory device or the memory cell of any one of Examples 1 to 12 may optionally include that the channel length is in the range from about 20% to about 80% of the gate length.

In Example 14, the memory device or the memory cell of any one of Examples 1 to 13 may optionally include that the gate structure defines a gate length, and that an overlap of the gate structure with the source region is greater than 10% of the gate length.

In Example 15, the memory device or the memory cell of any one of Examples 1 to 14 may optionally include that the gate structure defines a gate length, and that an overlap of the gate structure with the drain region is greater than 10% of the gate length.

In Example 16, the memory device or the memory cell of any one of Examples 1 to 15 may optionally include that the gate structure includes one or more electrode layers as gate electrode and/or one or more dielectric layer as gate isolation.

In Example 17, the memory device or the memory cell of any one of Examples 1 to 16 may optionally include that the spontaneously polarizable layer includes one or more spontaneously polarizable materials.

In Example 18, the memory device or the memory cell of any one of Examples 1 to 17 may optionally include that the spontaneously polarizable layer includes one or more remanently spontaneously polarizable materials.

In Example 19, the memory device or the memory cell of any one of Examples 1 to 18 may optionally include that the spontaneously polarizable layer includes one or more remanently spontaneously polarizable materials based on at least one of hafnium oxide and/or zirconium oxide.

In Example 20, the memory device or the memory cell of any one of Examples 1 to 19 may optionally include that the field-effect transistor structure is a fin field-effect transistor structure, or that the field-effect transistor structure is a trench field-effect transistor structure, or that the field-effect transistor structure is a planar field-effect transistor structure, or that the field-effect transistor structure is a nanosheet field-effect transistor structure, or that the field-effect transistor structure is a nanowire field-effect transistor structure.

In Example 21, the memory device or the memory cell of any one of Examples 1 to 20 may optionally include that the field-effect transistor structure includes a gate electrode configured as a floating gate of the memory cell.

In Example 22, the memory device or the memory cell of any one of Examples 1 to 21 may optionally include that the source region has a doping content greater than about 10¹⁸ /cm³, and/or that the drain region has a doping content greater than about 10¹⁸ /cm³.

In Example 23, the memory device or the memory cell of Example 22 may optionally include that the channel region has a doping content that is at least one order of magnitude lower than the doping content of the source region and/or of the drain region.

In Example 24, the memory device or the memory cell of any one of Examples 1 to 23 may optionally include that a lateral doping profile of the source region is equal to a lateral doping profile of the drain region.

In Example 25, the memory device or the memory cell of any one of Examples 1 to 24 may optionally include that a lateral doping profile of the source region is different from a lateral doping profile of the drain region.

Example 26 is a memory cell, including: a field-effect transistor structure and a capacitive memory structure, the capacitive memory structure including at least one spontaneously polarizable layer, the field-effect transistor structure including: a source region, a drain region, a channel region extending between the source region and the drain region, and a gate structure disposed at the channel region, wherein the gate structure substantially overlaps the source region and/or the drain region.

Example 27 is a memory cell, including: a field-effect transistor structure and a capacitive memory structure, the capacitive memory structure including at least one spontaneously polarizable layer, the field-effect transistor structure including: a source region, a drain region, a channel region extending between the source region and the drain region defining a channel length, and a gate structure disposed at the channel region, wherein the gate structure includes a gate electrode defining a gate length, and wherein the channel length is substantially shorter than the gate length.

Example 28 is a memory cell, including: a field-effect transistor structure and a capacitive memory structure, the capacitive memory structure including at least one spontaneously polarizable layer, the field-effect transistor structure including: a source region, a drain region, a channel region extending between the source region and the drain region defining a channel length, and a gate structure disposed at the channel region, wherein an overlap of the gate structure with the source region is different from an overlap of the gate structure with the drain region.

Example 29 is a memory cell, including: a field-effect transistor structure and a capacitive memory structure, the capacitive memory structure including at least one spontaneously polarizable layer, the field-effect transistor structure including: a source region, a drain region, a channel region extending between the source region and the drain region defining a channel length, and a gate structure disposed at the channel region, wherein the gate structure overlaps the source region and the drain region in an asymmetric configuration such that a capacitance associated with the drain region and the gate structure is different from a capacitance associated with the source region and the gate structure.

Example 30 is a method for operating a field-effect transistor based capacitive memory cell, the method including: writing (e.g., programming and/or erasing) the field-effect transistor based capacitive memory cell by providing a gate/source voltage drop, wherein the field-effect transistor based capacitive memory cell includes a field-effect transistor structure having a gate/source overlap.

Example 31 is a method for operating a field-effect transistor based capacitive memory cell, the method including writing (e.g., programming and/or erasing) the field-effect transistor based capacitive memory cell by providing a gate/drain voltage drop, wherein the field-effect transistor based capacitive memory cell includes a field-effect transistor structure having a gate/drain overlap.

Example 32 is a method for operating a field-effect transistor based capacitive memory cell having a field-effect transistor structure with a gate/drain overlap, the method including: writing and/or inhibiting the field-effect transistor based capacitive memory cell by applying a gate/drain voltage between a drain region of the field-effect transistor structure and a gate of the field-effect transistor based capacitive memory cell.

Example 32 is a method for operating a field-effect transistor based capacitive memory cell having a field-effect transistor structure with a gate/source overlap, the method including: writing and/or inhibiting the field-effect transistor based capacitive memory cell by applying a gate/source voltage between a source region of the field-effect transistor structure and a gate of the field-effect transistor based capacitive memory cell.

According to various aspects, a field-effect transistor structure and a capacitive memory structure of a field-effect transistor based capacitive memory cell may be coupled to one another by an ohmic connection between an electrode of the capacitive memory structure and a gate electrode of the field-effect transistor structure. According to various aspects, a field-effect transistor structure and a capacitive memory structure of a field-effect transistor based capacitive memory cell may be coupled to one another by a direct physical contact of an electrode of the capacitive memory structure and a gate electrode of the field-effect transistor structure. According to various aspects, a field-effect transistor structure and a capacitive memory structure of a field-effect transistor based capacitive memory cell may be coupled to one another by a shared electrode that acts as an electrode of the capacitive memory structure and as a gate electrode of the field-effect transistor structure. In such configurations, a second electrode of the capacitive memory structure may serve as a gate of the field-effect transistor based capacitive memory cell and the gate electrode of the field-effect transistor structure is a floating gate of the field-effect transistor based capacitive memory cell.

Various aspects are related to an overlap of a gate of a field-effect transistor structure with one or more source/drain regions of the field-effect transistor structure. A length of an overlap is, in some aspects, defined along a channel length of the field-effect transistor structure (e.g., along a curved cannel or planar channel). The channel length (or more general the length direction) of a field-effect transistor structure is defined, in some aspects, by a shortest distance along the channel region between the drain region and the source region (e.g., by a shortest distance between the drain region and the source region along a spatial course of the channel).

In some aspects, the length direction (see, for example, direction 101 in FIGS. 3A to 3F and FIGS. 4A to 4D) that may define a channel length and a gate length. A length of an overlap is defined, in some aspects, in the length direction.

The terms “at least one” and “one or more” may be understood to include any integer number greater than or equal to one, i.e., one, two, three, four, [...], etc. The term “a plurality” or “a multiplicity” may be understood to include any integer number greater than or equal to two, i.e., two, three, four, five, [...], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The word “over”, used herein to describe forming a feature, e.g., a layer “over” a side or surface, may be used to mean that the feature, e.g., the layer, may be formed “directly on”, e.g., in direct contact with, the implied side or surface. The word “over”, used herein to describe forming a feature, e.g., a layer “over” a side or surface, may be used to mean that the feature, e.g., the layer, may be formed “indirectly on” the implied side or surface with one or more additional layers being arranged between the implied side or surface and the formed layer.

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g., provided by a metal or degenerate semiconductor in absence of p-n junctions in the current path. The term “electrically conductively connected” may be also referred to as “galvanically connected”.

The term “spontaneously polarizable material” or “spontaneous-polarizable material” may be used herein with reference to a material or layer that has a polarization capability in addition to its dielectric polarization capability. A spontaneously-polarizable material may be or may include a spontaneously-polarizable material that shows a remanence, e.g., a ferroelectric material, and/or a spontaneously-polarizable material that shows no remanence, e.g., an anti-ferroelectric material.

Several aspects are described with reference to a structure (e.g., a field-effect transistor structure, e.g., a ferroelectric field-effect transistor structure, e.g., a capacitive memory structure) and it is noted that such a structure may include solely the respective element (e.g., a field-effect transistor, e.g., a ferroelectric field-effect transistor, e.g., a capacitive memory); or, in other aspects, a structure may include the respective element and one or more additional elements.

According to various aspects, a capacitive memory structure may include a ferroelectric capacitor (FeCAP) or an anti-ferroelectric capacitor (AFeCAP); or, in other aspects, a capacitive memory structure may include a ferroelectric capacitor or an anti-ferroelectric capacitor (AFeCAP), and one or more additional elements. According to various aspects, a capacitive memory structure may include a capacitive memory element, e.g., a ferroelectric layer, e.g., an anti-ferroelectric layer. According to various aspects, a field-effect transistor based capacitive memory structure may include a field-effect transistor structure and a capacitive memory structure coupled to or integrated in the field-effect transistor structure; or, in other aspects, a field-effect transistor based capacitive memory structure may include a field-effect transistor structure, capacitive memory structure, and one or more additional elements. According to various aspects, a field-effect transistor based capacitive memory structure may include a field-effect transistor structure and a capacitive memory element integrated in the field-effect transistor structure.

In some aspects, a capacitive memory element may be included in a memory cell. The capacitive memory structure may include at least one spontaneously polarizable memory element, e.g., the capacitive memory structure may include a single spontaneously polarizable memory element or the capacitive memory structure may include a plurality of spontaneously polarizable memory elements. An example for a spontaneously polarizable memory element may be a spontaneously polarizable capacitor. In addition to the one or more spontaneously polarizable memory elements (e.g., in addition to one or more spontaneously polarizable capacitors), the capacitive memory structure may include a lever capacitor. The lever capacitor may be connected between a lever node and the floating gate node of the memory cell. A lever voltage may be supplied to the lever node (e.g., via an additional control line, e.g., referred to as a lever line) to modify a voltage of the floating gate node to allow for a more efficient operation of the memory cell.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A field-effect transistor based capacitive memory cell, comprising:
a field-effect transistor structure and a capacitive memory structure, wherein the capacitive memory structure comprises at least one spontaneously polarizable memory element, and wherein the field-effect transistor structure comprises a source region, a drain region, a channel region extending between the source region and the drain region, and a gate structure disposed at the channel region,
wherein the gate structure of the field-effect transistor structure substantially overlaps the source region of the field-effect transistor structure and/or the drain region of the field-effect transistor structure.

2. The field-effect transistor based capacitive memory cell of claim 1,
wherein an overlap of the gate structure with the source region is different from an overlap of the gate structure with the drain region.

3. The field-effect transistor based capacitive memory cell of claim 1,
wherein the gate structure overlaps the source region and the drain region in an asymmetric configuration such that a capacitance associated with the drain region and the gate structure is different from a capacitance associated with the source region and the gate structure.

4. The field-effect transistor based capacitive memory cell of claim 1,
wherein a length of an overlap of the gate structure with the source region is greater than 5 nm, and/or wherein a length of an overlap of the gate structure with the drain region is greater than 5 nm.

5. The field-effect transistor based capacitive memory cell of claim 1,
wherein a drain overlap portion of the gate structure is in direct physical contact with a portion of the drain region, and wherein a source overlap portion of the gate structure is in direct physical contact with a portion of the source region, and wherein a length of the drain overlap portion of the gate structure is equal to a length of the source overlap portion of the gate structure.

6. The field-effect transistor based capacitive memory cell of claim 1,
wherein a drain overlap portion of the gate structure is in direct physical contact with a portion of the drain region, and wherein a source overlap portion of the gate structure is in direct physical contact with a portion of the source region, and wherein a length of the drain overlap portion of the gate structure is different from a length of the source overlap portion of the gate structure.

7. The field-effect transistor based capacitive memory cell of claim 1,
wherein the gate structure defines a gate length, and wherein a channel length of the field-effect transistor structure is substantially shorter than the gate length.

8. The field-effect transistor based capacitive memory cell of claim 1,
wherein the gate structure defines a gate length, and wherein a channel length is in the range from about 20% to about 80% of the gate length.

9. The field-effect transistor based capacitive memory cell of claim 1,
wherein the gate structure defines a gate length, and wherein an overlap of the gate structure with the source region is greater than 10% of the gate length.

10. The field-effect transistor based capacitive memory cell of claim 1,
wherein the gate structure defines a gate length, and wherein an overlap of the gate structure with the drain region is greater than 10% of the gate length.

11. The field-effect transistor based capacitive memory cell of claim 1,
wherein the gate structure comprises one or more electrode layers as gate electrode and one or more dielectric layer as gate isolation.

12. The field-effect transistor based capacitive memory cell of claim 1,
wherein the spontaneously polarizable memory element comprises one or more spontaneously polarizable materials.

13. The field-effect transistor based capacitive memory cell of claim 1,
wherein the spontaneously polarizable memory element comprises one or more remanently spontaneously polarizable materials.

14. The field-effect transistor based capacitive memory cell of claim 1,
wherein the field-effect transistor structure is a field-effect transistor structure of the following group of field-effect transistor structures:
a fin field-effect transistor structure,
a trench field-effect transistor structure,
a planar field-effect transistor structure,
a nanosheet field-effect transistor structure,
a nanowire field-effect transistor structure.

15. The field-effect transistor based capacitive memory cell of claim 1,
wherein the field-effect transistor structure comprises a gate electrode configured as a floating gate of the field-effect transistor based capacitive memory cell, wherein an electrode of the capacitive memory structure is configured as a gate of the field-effect transistor based capacitive memory cell.

16. The field-effect transistor based capacitive memory cell of claim 1,
wherein the channel region has a doping content that is at least one order of magnitude lower than a doping content of the source region and/or of the drain region.

17. The field-effect transistor based capacitive memory cell of claim 1,
wherein a lateral doping profile of the source region is equal to a lateral doping profile of the drain region.

18. The field-effect transistor based capacitive memory cell of claim 1,
wherein a lateral doping profile of the source region is different from a lateral doping profile of the drain region.

19. A method for operating a field-effect transistor based capacitive memory cell having a field-effect transistor structure with a gate/drain overlap, the method comprising:
writing and/or inhibiting the field-effect transistor based capacitive memory cell by applying a gate/drain voltage between a drain region of the field-effect transistor structure and a gate of the field-effect transistor based capacitive memory cell.

20. A method for operating a field-effect transistor based capacitive memory cell having a field-effect transistor structure with a gate/source overlap, the method comprising:
writing and/or inhibiting the field-effect transistor based capacitive memory cell by applying a gate/source voltage between a source region of the field-effect transistor structure and a gate of the field-effect transistor based capacitive memory cell.
